(19) United States
(12) Patent Application Publication
(10) Pub. No.: US 2011/0069540 A1
(43) Pub. Date: Mar. 24, 2011

(54) Method of a phase-change memory programming

(76) Inventor: Semyon D. Savransky, Newark, CA (US)

(21) Appl. No.: 12/924,167

(22) Filed: Sep. 22, 2010

Related U.S. Application Data
(60) Provisional application No. 61/277,304, filed on Sep. 23, 2009.

(51) Int. Cl. G11C 11/00

(52) U.S. Cl. 365/163; 365/148; 257/4

(57) ABSTRACT

A method of programming a phase-change memory (PCM) device to the high resistance reset state by means of pressure-induced amorphization. A train of few short bipolar current pulses is applied to the PCM device in order to stress phase-change alloy (PCA) under high pressure, and current in each pulse is almost equal to set current. An atomic structure of phase-change alloy is easily deformable by external pressure due to weak chemical bonds. Some materials mechanically contacted PCA in PCM have lower coefficients of thermal expansion and compressibility as well as higher coefficient of hardness than the corresponding coefficients of the PCA.

### CROSS REFERENCE TO RELATED APPLICATIONS

This application claims priority to and the benefit of, and incorporates herein by reference in its entirety, U.S. Provisional Patent Application No. 61/277,304 which was filed on Sep. 23, 2009.

### PROGRAM LISTING COMPACT DISK APPENDIX

Not Applicable.

### REFERENCE REGARDING FEDERAL SPONSORSHIP

Not Applicable.

### STATEMENT REGARDING FEDERALLY SPONSORED RESEARCH OR DEVELOPMENT

Not Applicable.

### BACKGROUND OF THE INVENTION

1. Field of the Invention

Electrical memory based on reversible transition of active material between various states, for example phase-change memory (PCM). The invention relates to an electrical memory and, in particular, to programming methods for PCM into reset states.

2. Description of Related Art

Phase-change memories consist of several PCM cells are non-volatile memory devices that store data using a phase-change alloy (PCA), the electric resistance of which varies upon a phase transition between two or more states. Phase-change memory (PCM) can be read and programmed very quickly and do not require power to maintain their state. Therefore, phase change devices are very useful devices for storing data (e.g., as a computer memory device). PCM cells have many of the advantages of both volatile memories such as dynamic random access memories and Flash non-volatile memories.

The known PCM works due to reversible transition between crystalline and amorphous phases in atomic structure of a phase-change alloy (PCA). The resistance of the PCA in the reset (amorphous) state is greater than the resistance of the PCA in the set (crystalline) state. These set and reset states can be assigned for different logic values, e.g. 1 and 0.

The transition from the amorphous to the crystalline phase occurs due to crystallization initiated by long electrical pulse with a moderate electrical current that heats up PCA to crystallization temperature Tx (so called set pulse).

The transition from the crystalline to amorphous phase in known methods of PCM programming occurs due to melting initiated by short electrical pulse with a high electrical current that heats up PCA above melting point Tm and fast PCA cooling (so called reset pulse).

The electric pulses or pulse trains produce Joule heating of active PCA volume in all prior art methods and embodiments of PCM programming methods. This current heats up active PCA to or above crystallization temperature Tx for the set state and to or above melting temperature Tm for the reset state due to the Joule effect. The PCA may change back and forth between a crystalline state and an amorphous state during a programming pulse when the current flows through a PCM. Because Tm is higher than Tx the reset current is larger than set current. High reset current is the main disadvantage of PCM to compare with other resistive memories.

As an example, a PCA may be heated to its melting point by applying a relatively high current (e.g., 3 mA) pulse to the PCA for a relatively short duration of time (e.g., 10 ns). The PCA may then be rapidly cooled, which changes the PCA to a highly resistive, amorphous state, named as reset state. When PCA in the reset state is heated above its crystallizing temperature by applying a relatively low current pulse (e.g., 500 uA) for relatively long time (e.g., 1 us) it changes to a lower resistive, crystalline state, named as set state.

In order to have good sense margin the ratio of set and reset resistances in PCM should be as high as possible. It is desirable also to spend small energy during PCM programming, to have high endurance of PCM, and to have tight distributions of parameters for set and reset PCM cells in a memory array.

There have been few attempts to reduce reset current by choosing PCA with small point, but such PCA do not satisfy other requirements of a non-volatile memory.

There have been several attempts to reduce reset current by decreasing amorphous region in PCM due to scaling of area between PCM electrode and active PCA volume. This approach required expensive photo-lithography or other methods to make characteristic device features as small as 32 nanometers.

There have been few attempts to reduce reset current by designing PCM with high thermal efficiency, but the best achieved efficiency of PCM is still less than 10 percent.

There have been few attempts to improve PCM by special programming techniques which we describe in details.

Lai and Lowrey, as reported in the paper “OUM-A 180 nm nonvolatile memory cell element technology for stand alone and embedded applications” published in Electron Devices Meeting, 2001. IEDM Technical Digest, 2-5 Dec. 2001 p. 36.5.1-36.5.4, used long (e.g., 500 ns) square pulse (FIG. 1A) to achieve a set state of phase change memory. Advantage of such set pulse is small energy for PCM programming in set state, disadvantage that not all cells in big array can be programmed with the same pulse. Lai and Lowrey, as reported in this paper used short (e.g., 100 ns) square pulse with high amplitude to melt PCA and then quench it in the reset state. Advantage of such reset pulse is simplicity of pulse generating circuit, disadvantage that some of cells in big array can be overheated because of difference in melting temperature Tm between different PCM cells. This causes low endurance of such PCM cells.

The following sections give comprehensive review of reset pulses proposed for PCM in the prior art that reflect improvements of Lai-Lowrey programming methods.

During reset pulse active volume of PCA should be obtained in mostly the solid amorphous state usually from previously mostly crystalline state. All kinds of reset pulses described in this section are based on vitrification of the melt.

Savransky proposed reset pulse with annealing portion (FIG. 1B) to decrease drift in PCA in white paper “Some Peculiarities of Reset Process and Reliability of Chalcogenide Phase-Change Non-Volatile Memory” (August 2005) published in the WWWeb (www.trizexperts.net).

Phillipp et. al., proposed in U.S. Pat. No. 7,577,023 “Memory Including Write Circuit For Providing Multiple Reset Pulses” (Aug. 18, 2009) to use few square reset pulses with decreasing amplitude to PCM cells with various critical dimension in array (FIG. 1C). At least the first pulse melts active material in a PCM cell. The second and following reset pulses with amplitude smaller than the amplitude of the first reset pulse can decrease the resistance of a PCM programmed to reset state by the first reset pulse, therefore decrease the read margin. On the other hand, the amplitude of the first reset pulse can be too high for the some PCM cells that can be programmed by the second and following reset pulses, therefore the first pulse reduce endurance of such PCM cells.

Phillipp et. al., proposed in US Patent Application 20090003035 “Conditioning Operations for Memory Cells” (January 2009) to use few successive square or trapezoidal reset pulses (FIG. 1D) with the same amplitude to condition a memory cell. Each of such pulses melts active material in a PCM cell. Such reset pulses train is longer than a single reset pulse, heat up the cell above melting point, and, hence, leads to smaller endurance of PCM.

Ming Hsiu Lee and Chou Chen proposed in U.S. Pat. No. 7,272,037 “Method for programming a multilevel phase-change memory device” (September 2007) different pulses for reset state with variable threshold switching voltage. Each of their pulses required to melt PCA and then cool down in high resistive state.

Jun-Soo Bae et. al., proposed US Patent Application 2009/0073754 reset pulses with rising time longer than failing time for MLC programming of PCM. Each of such pulses melts active material in a PCM cell, and, hence, uses high current for programming.

Savransky proposed unipolar reset pulses train for pressure induced amorphization of a phase change alloy in U.S. Provisional Application No. 61/096,864 (September 2008). Such high duty pulse train allows program PCM below melting temperature but it is quite difficult to generate this train within a chip.

High programming reset current limits usability of phase-change memory for several applications there battery supplies energy for a memory chip.

What is needed in the art is the method of programming of the phase-change memory (PCM) into high resistance amorphous reset state with small current. Also related phase-change alloys (PCA) and memory cells programmable with small current are desirable.

### BRIEF DESCRIPTION OF THE DRAWINGS

The invention is illustrated by way of example and not by way of limitation in the figures of the accompanying drawings in which like references indicate similar elements. It should be noted that references to “an” embodiment in this disclosure are not necessarily to the same embodiment, and they mean at least one.

FIG. 1A shows pulses for programming a phase-change memory used by Lai and Lowrey. The amplitudes and durations of reset and set pulses are shown for the comparison; Tm and Tx are melting and crystallization temperatures that are achieved during the reset and set pulses.

FIG. 1B shows reset pulse with annealing for drift-free programming a phase-change memory used by Savransky.

FIG. 1C shows square reset pulses with decreasing amplitude proposed by Savransky.

FIG. 1D shows few successive square reset pulses proposed by Phillipp et. al with the same or decreasing amplitude where the lowest amplitude of a pulse brings PCA above the melting point Tm.

FIG. 1E shows unipolar reset pulses train proposed by Savransky for sub-melting PCA programming.

FIG. 2 shows a generic phase-change memory device.

FIG. 3 shows bipolar reset pulses train for sub-melting PCA programming according to an embodiment of the invention.

FIG. 4 shows a generic phase-change memory device according to an embodiment of the invention.

### DETAILED DESCRIPTION

The present invention explores a new way to obtain the reset state in phase-change memory (PCM) by means of pressure-induced amorphization (sometimes called as stressor mechanical-induced amorphization), a new construction of PCM device and a new PCA that increase efficiency of pressure-induced amorphization.

Many PCA have higher atomic density in amorphous state than in crystalline state. Therefore pressure can transform crystalline PCA into amorphous state as was demonstrated in the paper “Pressure-Induced Site-Selective Disordering of Ge2Sb2Te5: A New Insight into Phase-Change Optical Recording” by A. V. Kolobov, J. Haines, A. Pradel, M. Ribes, P. Fons, J. Tominaga, Y. Katayama, T. Hammouda, and T. Uruga published in Phys. Rev. Lett. 97, 035701 (2006).

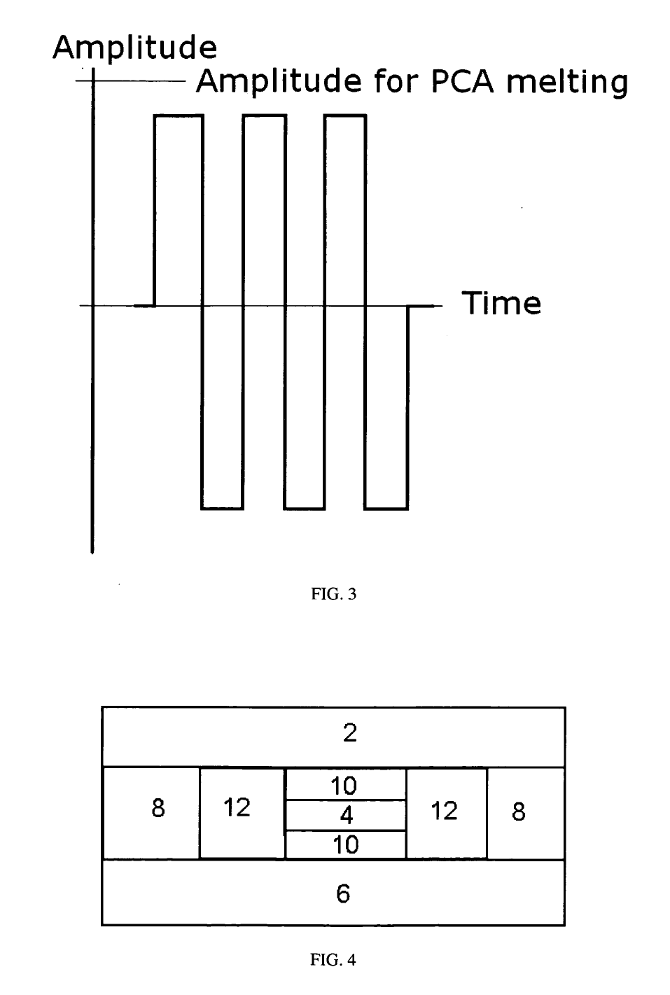

According to an embodiment of the invention, the programming a phase-change memory in high resistance amorphous reset state due to pressure-induced amorphization is occurred by application to PCM several short bipolar pulses shown in FIG. 3. Such pulses are also referred to here as a “reset train”. With the reset train the phase-change alloy in PCM device can reach temperatures lower than the melting point Tm yet still change to the reset state, due to the pressure on PCA because of mechanical stresses in the PCM device. This means that the reset current amplitude in the memory has decreased, therefore lowering power needed to program PCM.

FIG. 2 illustrates a generic phase-change memory device, according to an embodiment of the invention. Conductive electrodes 2 and 6 are in mechanical and electrical contacts with a phase-change alloy 4. Insulator 8 is in mechanical contact with the phase-change alloy 4 and electrodes 2 and 6. The electrodes 2 and 6 can be made from a metal (e.g., Ti or Pt or Pt—Ir or Mo), conductive carbon or conductive composite (e.g., TaSiN or TiSiAl) or another non-elastic conductive material with high hardness. The insulator 8 can be made from SiO2 or Si3N4 or another non-elastic nonconductive material with high hardness (for example, with Brinell hardness higher than 600). The phase change alloy (PCA) 4 consists of at least one pnictogen (for example, Sb) and at least one chalcogen (for example, Te) and can contain one or more chemical elements (for example, H, F, In, Sn, Bi) that form atomic bond with a pnictogen or/and a chalcogen with energy smaller than the energy of the bond between said pnictogen and chalcogen. The atomic structure of said phase-change material is easily deformable by external pressure due to significant concentration of vacancies and it examples are H—Sb—Te or F—Sb—Se—Te or Ge—Sb—Te or Bi—Sb—Te or In—Sb—Te or Sb—In—Ge—Te.

The coefficients of thermal expansion and the compressibilities of the electrodes 2 and 6 and the insulator 8 are smaller than the coefficients of thermal expansion and the compressibility of the PCA 4 in PCM device. The hardness and elastic modulus of PCA 4 are smaller than hardnesses and elastic modules of the electrodes 2 and 6 and the insulator 8 in PCM device.

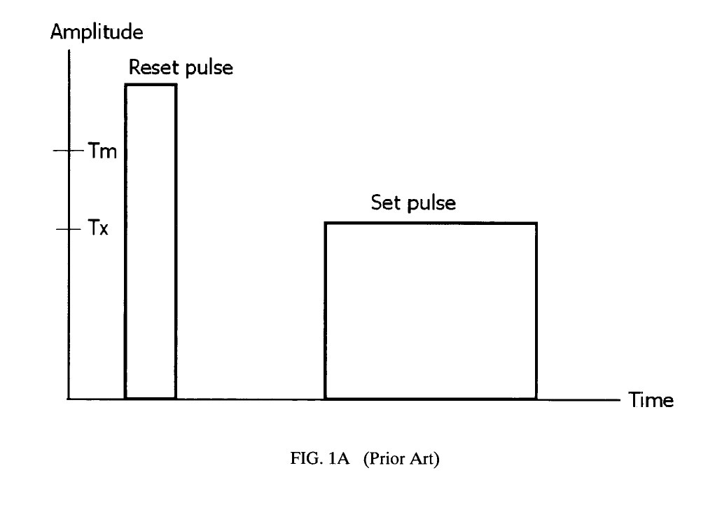

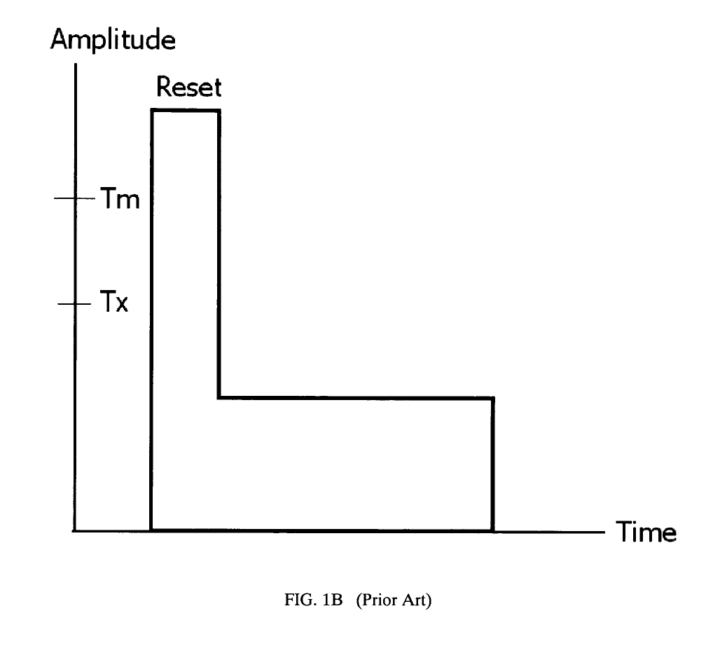

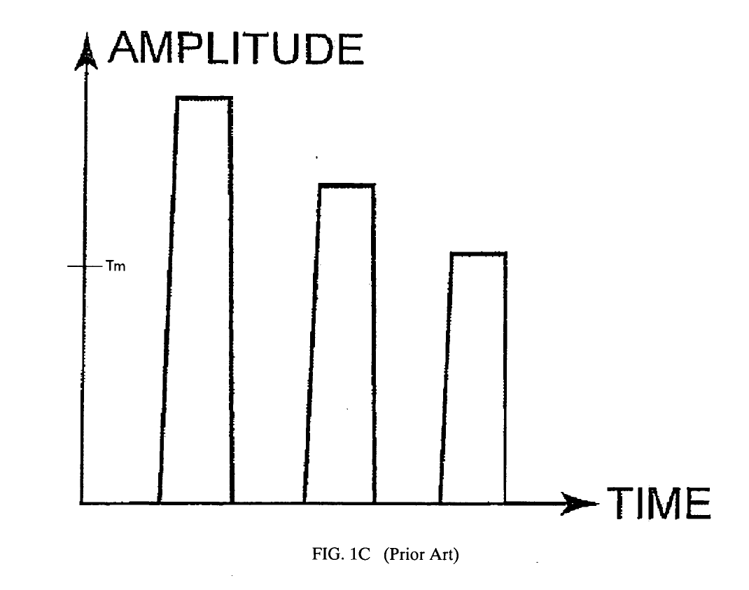

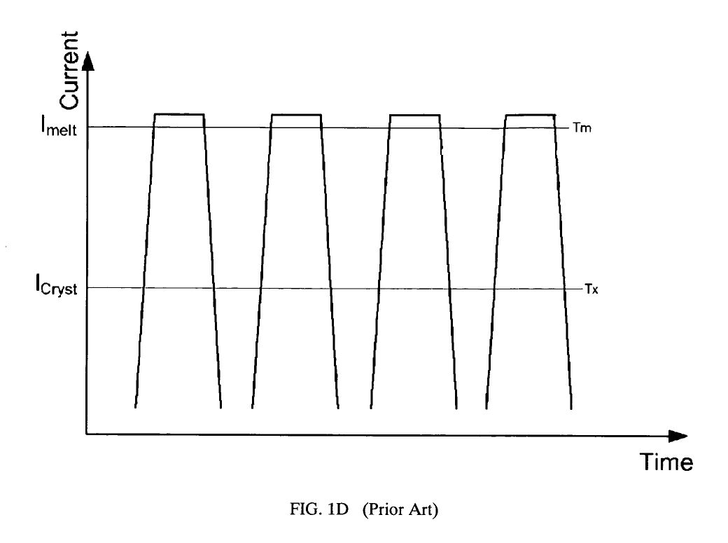

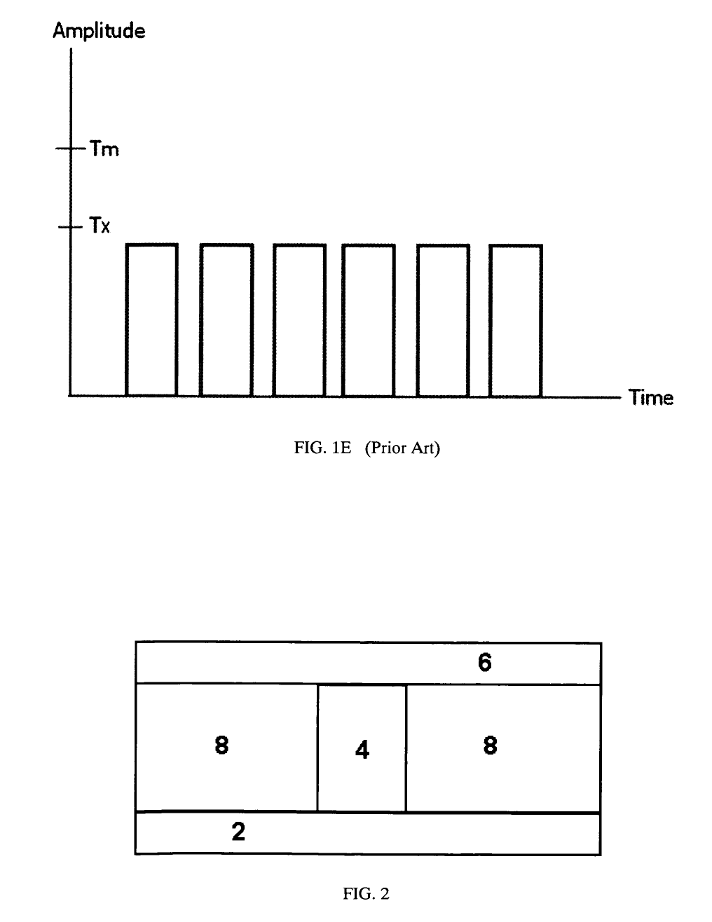

The programming of PCM device in the set state occurs by relatively electrical long pulses (e.g., 200 ns) shown in FIG. 1A as it is known in the art.

The programming of PCM device in the reset state occurs according to embodiments of this invention by the bipolar reset train of N short pulses (e.g., 10 ns), where number of pulses N is between 2 and 1000 and each pulse has leading and trailing edges between 100 ps and 10 ns. The maximum current amplitude of each of these short pulses is not enough to melt PCA 4, although they heat up the PCA 4 below melting temperature Tm. The pulses of reset train heat up PCA 4 above crystallization temperature Tx in some embodiments. A pulse in the reset train can be rectangular or triangle or trapezoidal or have another shape with sharp leading and falling edges from 0.01 picoseconds to 200 nanoseconds and pulse duration from 1 picoseconds to 100 milliseconds.

The bipolar reset train shown in FIG. 3 applied to set PCM leads to significant thermal expansion of the PCA 4 but relatively small thermal expansions of the electrodes 2 and 6 and the insulator 8. Mismatch of the thermal expansions creates strong pressure and mechanical stresses in the PCA 4 that leads to amorphization of the PCA 4. As the result of the amorphization PCA 4 becomes high resistive and PCM device is converted into reset state. Any known in the art set pulse converts the PCA 4 back into crystalline low resistance state. Such cycle can be repeated many times and both set and reset states obtained by reset train and any known set pulse are non-volatile and can be used to store information in PCM device.

In order to increase efficiency of the reset train various embodiments of PCM device are proposed, generic one is shown in the FIG. 4. The PCM device in an embodiment has conductive electrodes 2 and 6, phase-change alloy 4, and insulator 8 as well as conductive layer 10 in mechanical and electrical contact with the PCA 4 and/or nonelastic casing 12 in mechanical contact with the PCA 4 in some embodiments. The compressibilities of the layer 10 and/or the casing 12 are smaller than compressibilities of the electrodes 2 and 6 and the insulator 8 in some embodiments. The hardnesses of the layer 10 and/or the casing 12 are higher than the hardnesses of the electrodes 2 and 6 and insulator the 8 in some embodiments.

The thermal expansion coefficients of the layer 10 and/or the casing 12 are smaller than the thermal expansion coefficients for the electrodes 2 and 6 and the insulator 8 in some embodiments.

The layer 10 can be made from titanium niobium TiNb or samarium titanium niobium SmTiNb alloys.

The casing 12 can be made from an electrostrictive material, such as lead magnesium niobate (PMN), lead magnesium niobate-lead titanate (PMN-PT) or lead lanthanum zirconate titanate (PLZT) in some embodiments.

The main advantage of this invention is the low current during bipolar reset train which can be easily generated inside a memory chip.

To summarize, various embodiments of a phase-change memory programming technique, referred to as a reset train, various embodiments of a phase-change material, and various embodiments of a phase-change memory device have been described. In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

Although a preferred embodiment of the present invention has been described for illustrative purposes, those skilled in the art will appreciate that various modifications, additions and substitutions are possible, without departing from the scope and spirit of the invention as disclosed in the accompanying main claims.

I claim:

1. A method of operating a phase-change memory device programmable to a plurality of high resistance states by train of bipolar electrical signals applying to said memory device.

2. The method of claim 1, wherein said electrical programming of said memory device to said high resistance state occurs due to pressure-induced amorphization of said phase-change alloy.

3. The method of claim 1, wherein said electrical signal amplitude for any polarity is not big enough to melt said phase-change alloy in said memory device.

4. The method of claim 1, wherein said electrical signals are trapezoidal pulses, wherein said trapezoidal pulse has trailing and falling edges from 0.01 picoseconds to 200 nanoseconds and pulse duration from 1 picosecond to 100 milliseconds.

5. The method of claim 1, wherein said electrical signals are rectangular pulses or triangular pulses or free-shape pulses with uniform or non-uniform amplitudes and/or durations.

6. The method of claim 1, wherein said train has from 2 to 1000 pulses with duty cycle from 15% to 95% delivered from a voltage source or a current source or an another source of energy.

7. The method of claim 1, wherein present and desired device states are compared in order to reduce number of pulses in said train.

8. The method of claim 1, wherein parameters of said electrical signals have the optimized functional dependence to achieve the highest resistance of said memory device in shortest time with smallest energy consumption.

9. The method of claim 1, wherein said number of pulses in said selected so said high resistance of said memory element exceeds the predetermined resistance value.

10. A memory storage and retrieval device, comprising: (a) an electrically conductive first electrode; (b) an electrically conductive second electrode; and (c) a phase-change material stack between said first and second electrodes, said phase-change material has variable electrical conductivity, said electrical conductivity can be changed upon application of an electrical potential difference or electrical current between said first and second electrically conductive electrodes during programming of said device according to the claim 1.

11. The memory storage and retrieval device according to claim 10, wherein: said electrodes consist of single layer or several layers of relatively conductive materials and/or said phase-change material consists of a single phase-change alloy or multiple phase-change alloys mixed together or layered between said first electrode and said second electrode.

12. The memory storage and retrieval device according to claim 10, wherein: thermal expansion coefficient of at least one of said electrodes is lower than thermal expansion coefficient of said phase-change material.

13. The memory storage and retrieval device according to claim 10, wherein: compressibility of at least one of said electrodes is lower than compressibility of said phase-change material.

14. The memory storage and retrieval device according to claim 10, wherein: of at least one of said electrodes is higher than hardness of said phase-change material.

15. The memory storage and retrieval device according to claim 10, wherein: of at least one of said electrodes is higher in two times than hardness of said phase-change material.

16. A memory storage and retrieval device, comprising: (a) an electrically conductive first electrode; (b) an electrically conductive second electrode; and (c) a phase-change material with variable electrical conductivity stack between said first and second electrodes; (c) a casting material, said casting material has electrostriction, said electrical conductivity can be changed upon application of an electrical potential difference or electrical current between said first and second electrically conductive electrodes during programming of said device according to the claim 1.

17. The memory storage and retrieval device according to claim 16, wherein: thermal expansion coefficient of said casting material is lower than thermal expansion coefficient of at least one of said electrodes.

18. The memory storage and retrieval device according to claim 16, wherein: compressibility of said casting material is lower than compressibility of at least one of said electrodes.

19. The memory storage and retrieval device according to claim 16, wherein: hardness of said casting material is higher than hardness of at least one of said electrodes.

20. An apparatus comprising a write circuit producing train of bipolar pulses according to claim 1 coupled with a memory.
